(19) United States
(12) Patent Application Publication
(10) Pub. No.: US 2014/0264493 A1
(43) Pub. Date: Sep. 18, 2014

(54) Semiconductor Device and Fabricating the Same

(71) Applicant: TAIWAN SEMICONDUCTOR MANUFACTURING COMPANY, LTD., Hsin-Chu (TW)

(72) Inventors: Yu-Hung Cheng, Tainan City (TW); Ching-Wei Tsai, Taoyuan City (TW); Wen-Hsing Hsieh, Hsinchu City (TW); Cheng-Ta Wu, Shueishang Township (TW); Yeur-Luen Tu, Taichung (TW)

(21) Appl. No.: 13/871,465

(22) Filed: Apr. 26, 2013

Related U.S. Application Data
(60) Provisional application No. 61/778,693, filed on Mar. 13, 2013.

(51) Int. Cl. H01L 29/78; H01L 29/66

(52) U.S. Cl. CPC H01L 29/785; H01L 29/66795
USPC 257/288; 438/283

(57) ABSTRACT

A semiconductor device includes a substrate, a gate stack having at least one gate vertex directed to an area in the substrate below the gate stack. The semiconductor device also includes a source structure having at least one vertex directed toward the area in the substrate and a drain structure having at least one vertex directed toward the area in the substrate.

The present patent claims the benefit of U.S. Ser. No. 61/778,693 filed Mar. 13, 2013, the disclosure of which is hereby incorporated by reference

### BACKGROUND

The semiconductor integrated circuit (IC) industry has experienced rapid growth in the past several decades. Technological advances in semiconductor materials and design have produced increasingly smaller and more complex circuits. These material and design advances have been made possible as the technologies related to processing and manufacturing have also undergone technical advances. As a size of the smallest component has decreased, numerous challenges have risen. For example, a three dimensional transistor, such as a fin-like field-effect transistor (FinFET), has been introduced. Although existing devices and methods of fabricating devices have been generally adequate for their intended purposes, they have not been entirely satisfactory in all respects. For example, a limitation of an effective gate length raises challenges in semiconductor device development, including with FinFETs. It is desired to have improvements in this area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of an example method for fabricating a semiconductor device according to various aspects of the present disclosure.

FIGS. 2 to 6 illustrates cross sectional views of an example semiconductor device at fabrication stages constructed according to the method of FIG. 1.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Examples of semiconductor devices that can benefit from one or more embodiments of the present application are semiconductor devices. The semiconductor device, for example, may be a complementary metal-oxide-semiconductor (CMOS) device comprising a P-type metal-oxide-semiconductor (PMOS) device and an N-type metal-oxide-semiconductor (NMOS) device. The following disclosure will continue with a semiconductor device example to illustrate various embodiments of the present application. It is understood, however, that the application should not be limited to a particular type of device, except as specifically claimed.

FIG. 1 is a flowchart of one embodiment of a method 100 of fabricating one or more semiconductor devices according to aspects of the present disclosure. The method 100 is discussed in detail below, with reference to an integrated circuit (IC) device 200 shown in FIGS. 2 to 6 for the sake of example.

Referring to FIGS. 1 and 2, the method 100 begins at step 102 by providing a substrate 210. The substrate 210 may be a bulk silicon substrate. Alternatively, the substrate 210 may comprise an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Possible substrates 210 also include a silicon-on-insulator (SOI) substrate. SOI substrates are fabricated using separation by implantation of oxygen (SIMOX), wafer bonding, and/or other suitable methods.

The substrate 210 may include various doped regions depending on design requirements as known in the art. The doped regions may be doped with p-type dopants, such as boron or BF2; n-type dopants, such as phosphorus or arsenic; or combinations thereof. The doped regions may be formed directly on the substrate 210, in a P-well structure, in an N-well structure, in a dual-well structure, or using a raised structure. The substrate 210 may further include various active regions, such as regions configured for an N-type metal-oxide-semiconductor transistor device and regions configured for a P-type metal-oxide-semiconductor transistor device.

For a FinFET, the substrate 210 may include a plurality of fins formed by any suitable process including various deposition, photolithography, and/or etching processes. For example, fins are formed by patterning and etching the substrate 210.

The substrate 210 may include isolation regions 212 to isolate active regions of the substrate 210. The isolation region 212 may be formed using traditional isolation technology, such as shallow trench isolation (STI), to define and electrically isolate the various regions. The isolation region 212 comprises silicon oxide, silicon nitride, silicon oxynitride, an air gap, other suitable materials, or combinations thereof. The isolation region 212 is formed by any suitable process. As one example, the formation of an STI includes a photolithography process, an etch process to etch a trench in the substrate (for example, by using a dry etching and/or wet etching), and a deposition to fill in the trenches (for example, by using a chemical vapor deposition process) with one or more dielectric materials. The trenches may be partially filled, as in the present embodiment, where the substrate remaining between trenches forms a fin structure. In some examples, the filled trench may have a multi-layer structure such as a thermal oxide liner layer filled with silicon nitride or silicon oxide.

Referring again to FIGS. 1 and 2, the method 100 proceeds to step 104 by forming a first gate stack 220 over the substrate 210, including over (wrapping) a portion of fins in a FinFET, and a gate spacer 225 along sidewalls of the first gate stack 220. The first gate stack 220 may include a dielectric layer and a gate electrode layer. The first gate stack 220 can be formed by a procedure including deposition, photolithography patterning, and etching processes. The deposition processes may include chemical vapor deposition (CVD), physical vapor deposition (PVD), atomic layer deposition (ALD), or other suitable processes. The photolithography patterning processes may include photoresist coating (e.g., spin-on coating), soft baking, mask aligning, exposure, post-exposure baking, developing the photoresist, rinsing, drying (e.g., hard baking), other suitable processes, and/or combinations thereof. The etching processes include dry etching, wet etching, and/or other etching methods.

In present embodiment, the first gate stack 220 is a dummy gate stack and is replaced later by a second gate stack. The dummy gate stack 220 may include the dielectric layer and the polysilicon layer.

The gate spacers 225 include a dielectric material such as silicon oxide. Alternatively, the gate spacers 225 may include silicon nitride, silicon carbide, silicon oxynitride, or combinations thereof. The gate spacers 225 may be formed by depositing a dielectric material over the first gate stack 220 and then anisotropically etching back the dielectric material.

Referring to FIGS. 1 and 3, the method 100 proceeds to step 106 by removing portions of the substrate 210, including portions of fins, at either side of the first gate stack 220 to form recesses 230A and 230B (collectively referred to as recesses 230). In the depicted embodiment, the recesses 230 are formed in a source region and a drain region, such that the first gate stack 220 interposes the recesses 230. They are referred to as the source recess 230A and the drain recess 230B. The recessing process may include dry etching process, wet etching process, and/or combination thereof. The recessing process may also include a selective wet etch or a selective dry etch. A wet etching solution includes a tetramethylammonium hydroxide (TMAH), a HF/HNO3/CH3COOH solution, or other suitable solution. The dry etching process may implement fluorine-containing gas (e.g., CF4, SF6, CH2F2, CHF3, and/or C2F6), chlorine-containing gas (e.g., Cl2, CHCl3, CCl4, and/or BCl3), bromine-containing gas (e.g., HBr and/or CHBR3), iodine-containing gas, other suitable gases and/or plasmas, and/or combinations thereof. The etching process may include a multiple-step etching to gain etch selectivity, flexibility and desired etch profile.

The etching process is controlled to achieve a desired profile of the recesses 230A and 230B. In the present embodiment, a profile of the recess 230A and 230B is formed to have at least one vertex 232A and 232B, respectively, of facets directed towards the first gate stack 220, as illustrated in FIG. 3. As an example, the vertex 232A is formed by two Si facets having (111) crystallographic orientation. A first distance d₁ is defined as the distance between two nearest source and drain vertexes, 232A and 232B. In the present embodiment, the gate 220 with sidewall spacers 225 has a width greater than 30 nm, and the first distance d₁ is equal or less than 30 nm. Although shown as points in the figures, in some embodiments, the source and drain vertexes, 232A and 232B can be rounded, and have a width that is equal to or less than 3 nm.

Referring to FIGS. 1 and 4, the method 100 proceeds to step 108 by forming epitaxial structures 240A and 240B (collectively referred to as epitaxial structures 240) in recesses 230A and 230B, respectively. In the present embodiment, the epitaxial structures 240 include a source/drain structure. The source/drain epitaxial structures 240 are formed by epitaxially growing a semiconductor material 242 in recesses 230. As a result, at least a portion of the source/drain epitaxial structure 240 has the same profile as the recesses 230.

The semiconductor material 242 includes single element semiconductor material such as germanium (Ge) or silicon (Si); or compound semiconductor materials, such as gallium arsenide (GaAs), aluminum gallium arsenide (AlGaAs); or semiconductor alloy, such as silicon germanium (SiGe), gallium arsenide phosphide (GaAsP). In one embodiment the semiconductor material 242 is different than the material of the substrate 210. The source/drain epitaxial structures 240 have a suitable crystallographic orientation (e.g., a (100), (110), or (111) crystallographic orientation). In an example, where an NFET device is desired, the source/drain epitaxial structures 240 may include an epitaxially growing silicon (epi Si) 242. In another example where a PPFET device is desired, source/drain epitaxial structures 240 may include an epitaxially growing silicon germanium (SiGe) 242. The source/drain epitaxial structures 240 may be formed by one or more epitaxy or epitaxial (epi) processes. The epitaxial processes may include CVD deposition techniques (e.g., vapor-phase epitaxy (VPE) and/or ultra-high vacuum CVD (UHV-CVD)), molecular beam epitaxy, and/or other suitable processes.

The source/drain epitaxial structures 240 may be in-situ doped or undoped during the epi process. For example, the epitaxially grown SiGe source/drain features 240 may be doped with boron; and the epitaxially grown Si epi source/drain features may be doped with carbon, phosphorous, or both. If the source/drain epitaxial structures 240 are not in-situ doped, a second implantation process (e.g., a junction implant process) is performed to dope the source/drain epitaxial structures 240. One or more annealing processes may be performed to activate source/drain dopants in the epitaxial structures. The annealing processes may include rapid thermal annealing (RTA) and/or laser annealing processes.

Referring to FIGS. 1 and 5A, the method 100 proceeds to step 110 by removing the first gate stack 220 and further etching the substrate 210, including fins, to form a gate trench 250. The etching processes may include selective wet etch or selective dry etch, such that having an adequate etch selectivity with respect to the gate spacer 225. The etching process may be similar in many respects to those discussed above in association with FIG. 3. In the present embodiment, the gate trench 250 is formed with a profile having at least one gate vertex 255. In one embodiment, the gate vertex 255 is formed at a bottom of the gate trench 250 by two (111) facets of the Si substrate 210. In the present embodiment, a second perpendicular distance d₂ between the gate vertex 255 and a horizontal line A-A connecting the source and drain vertexes, 232A and 232B is equal to or less than 20 nm. Although shown as a point in the figures, in some embodiments, the gate vertex 255 can be rounded, and have a width that is equal to or less than 3 nm.

In another embodiment, after forming the gate trench 250, an ion-implantation is performed to dope a targeted region 256 in the substrate 210, located between the gate vertex 255, the source vertex 232A and drain vertex 232B, as shown in FIG. 5B.

Referring to FIGS. 1 and 6, the method 100 proceeds to step 112 by forming a second gate stack 260 in the gate trench 250. The second gate stack 260 may include a dielectric layer 262 and a gate electrode layer 264. It is understood that the gate stack may include additional layers such as interfacial layers, capping layers, diffusion/barrier layers, dielectric layers, conductive layers, other suitable layers, and/or combinations thereof. For example, the dielectric 262 may include an interfacial layer (IL) and a gate dielectric layer. An exemplary IL includes silicon oxide (e.g., thermal oxide or chemical oxide) and/or silicon oxynitride (SiON). The gate dielectric layer may include a dielectric material, such as silicon oxide, silicon nitride, silicon oxynitride, high-k dielectric material, other suitable dielectric material, and/or combinations thereof. Examples of high-k dielectric material includes HfO2, HfSiO, HfSiON, HfTaO, HfTiO, HfZrO, zirconium oxide, aluminum oxide, hafnium dioxide-alumina (HfO₂—Al₂O₃) alloy, other suitable high-k dielectric materials, and/or combinations thereof.

The gate electrode layer 264 includes any suitable material, such as polysilicon, aluminum, copper, titanium, tantulum, tungsten, molybdenum, tantalum nitride, nickel silicide, cobalt silicide, TiN, WN, TiAl, TiAlN, TaCN, TaC, TaSiN, metal alloys, other suitable materials, and/or combinations thereof.

The gate dielectric layer 262 and gate electrode layer 264 may be deposited by chemical vapor deposition (CVD), physical vapor deposition (PVD), atomic layer deposition (ALD), or other suitable methods, and/or combinations thereof.

A dielectric layer 270 is deposited over the substrate 210, including over the source/drain epitaxial structures 240 and the second gate stack 250. The dielectric layer 270 includes silicon oxide, silicon nitride, silicon carbide, oxynitride or other suitable materials. The dielectric layer 270 is deposited by a suitable technique, such as CVD, ALD, PVD, thermal oxidation, or combinations thereof. Additionally, a CMP process is performed to planarize the top surface of the second gate stack 260 and the dielectric layer 270.

Additional steps can be provided before, during, and after the method 100, and some of the steps described can be replaced, eliminated, or moved around for additional embodiments of the method 100. The IC device 200 may include additional features, which may be formed by subsequent processing. For example, various contacts/vias/lines and multilayer interconnect features (e.g., metal layers and interlayer dielectrics) may be formed over the substrate, configured to connect the various features or structures of the IC device 200. For example, a multilayer interconnection includes vertical interconnects, such as conventional vias or contacts, and horizontal interconnects, such as metal lines. The various interconnection features may implement various conductive materials including copper, tungsten, and/or silicide.

Based on the above, the present disclosure presents a semiconductor device and fabrication. The semiconductor device employs vertex structures for each of gate stack, source and drain structures. Vertexes of the gate, source and drain are formed to be separated with a quite small distance to each other. The semiconductor device also has an option of having a doped region located between vertexes of the gate stack, the source and the drain. Thus semiconductor device can work as a tunneling device, or a single electron transistor (SET), and demonstrates advances of small gate length, low Vt, low power consumption.

The present disclosure provides many different embodiments of semiconductor device that provide one or more improvements over other existing approaches. In one embodiment, the semiconductor device includes a substrate, a gate stack having at least one gate vertex directed to an area in the substrate below the gate stack. The semiconductor device also includes a source structure having at least one vertex directed toward the area in the substrate and a drain structure having at least one vertex directed toward the area in the substrate.

In another embodiment, a field-effect transistor (FET) includes a substrate, a high-k/metal gate (HK/MG) stack having a bottom profile with a gate width and a gate vertex extending into the substrate. The FET also includes epitaxial source and drain structures disposed on each side of the HK/MG stack. The epitaxial source/drain structures each includes a vertex extending towards each other. A first distance between the source and drain vertexes is less than the gate width and a second distance from the gate vertex to a line connecting the source and drain vertexes is less than the first distance.

In yet another embodiment, a method for fabricating a semiconductor device includes providing a substrate, forming a first gate stack over a substrate, etching portions of the substrate to form a source and a drain recesses such that the gate structure interposes the source and drain recesses. The source and drain recesses include a profile which has at least one source/drain vertex towards the first gate stack. A first distance separates the source vertex and drain vertex. The method also includes forming source and drain structures over the recesses, removing the first gate stack to form a gate trench. The gate trench has at least one gate vertex directed towards the source/drain vertexes. The method also includes forming a second gate stack over the gate trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a gate stack having at least one gate vertex directed to an area in the substrate below the gate stack;
a source structure having at least one vertex directed toward the area in the substrate; and
a drain structure having at least one vertex directed toward the area in the substrate.

2. The semiconductor device of claim 1, wherein the source vertex is separated from the drain vertex by a first distance, and wherein the first distance is equal or less than about 30 nm.

3. The semiconductor device of claim 2, wherein the gate vertex is away from a line between the source and drain vertexes by a second distance, and wherein the second distance is equal to or less than about 20 nm.

4. The semiconductor device of claim 1, wherein the gate vertex has a minimum dimension which is equal or less than 3 nm.

5. The semiconductor device of claim 1, wherein the source/drain structure has a material which is different than the substrate.

6. The semiconductor device of claim 2, wherein the gate stack includes a high-k dielectric, gate sidewalls, and a metal gate, and has a width greater than 30 nm.

7. The semiconductor device of claim 1, wherein the gate vertex has two facets and the two facets have a silicon (111) crystallographic orientation.

8. The semiconductor device of claim 1, wherein the source/drain vertex has two facets and the two facets have a silicon (111) crystallographic orientation.

9. The semiconductor device of claim 1, wherein the gate stack is formed over a portion of fin.

10. The semiconductor device of claim 1, further comprising:
a doped region positioned between the gate vertex, the source vertex and adjacent drain vertex.

11. A field-effect transistor (FET) comprising:
a substrate;
a high-k/metal gate (HK/MG) stack having a bottom profile with a gate width and a gate vertex extending into the substrate; and
epitaxial source and drain structures disposed on each side of the HK/MG stack, the epitaxial source/drain structures each including a vertex extending towards each other;
wherein a first distance between the source and drain vertexes is less than the gate width; and
wherein a second distance from the gate vertex to a line connecting the source and drain vertexes is less than the first distance.

12. The FET of claim 11, wherein the first distance is less than about 30 nm, the second distance is less than about 20 nm, and the gate vertex has a minimum dimension which is equal to or less than 3 nm.

13. The FET of claim 11, further comprising:
a doped region positioned between the gate vertex, the source vertex and adjacent drain vertex.

14. A method comprising:
providing a substrate;
forming a first gate stack over a substrate;
etching portions of the substrate to form a source and a drain recesses such that the gate structure interposes the source and drain recesses, the source and drain recesses including a profile which has at least one source/drain vertex towards the first gate stack and a first distance separating the source vertex and drain vertex;
forming source and drain structures over the recesses;
removing the first gate stack to form a gate trench, which has at least one gate vertex directed towards the source/drain vertexes; and
forming a second gate stack over the gate trench.

15. The method of claim 14, wherein each of the source/drain vertexes is formed to have two silicon facets having (111) crystallographic orientations.

16. The method of claim 14, wherein the gate vertex is formed to have two silicon facets having (111) crystallographic orientations.

17. The method of claim 14, wherein the first distance is equal to or less than about 30 nm.

18. The method of claim 14, wherein the second distance is equal to or less than 20 nm.

19. The method of claim 14, wherein the gate vertex is formed having a minimum dimension of 3 nm or less.

20. The method of claim 14, further comprising:
prior to forming the second gate stack, applying ion-implantation through the gate trench.
